(19) United States
(12) Patent Application Publication
(10) Pub. No.: US 2017/0062460 A1
(43) Pub. Date: Mar. 2, 2017

(54) SEMICONDUCTOR MEMORY DEVICE AND METHOD FOR MANUFACTURING SAME

(71) Applicant: Kabushiki Kaisha Toshiba, Minato-ku (JP)

(72) Inventors: Daisuke NISHIDA, Mie (JP); Kazuhiro Matsuo, Kuwana (JP)

(73) Assignee: Kabushiki Kaisha Toshiba, Minato-ku (JP)

(21) Appl. No.: 15/008,579

(22) Filed: Jan. 28, 2016

Related U.S. Application Data
(60) Provisional application No. 62/209,482, filed on Aug. 25, 2015.

(51) Int. Cl. H01L 27/115

(52) U.S. Cl. CPC H01L 27/11582; H01L 27/11568

(57) ABSTRACT

According to one embodiment, a semiconductor memory device includes a substrate; a stacked body provided on the substrate and including: a first electrode layer including a first portion and a second portion thicker than the first portion in stacking direction of the stacked body; and an insulating layer provided between the first electrode layer and the substrate; a semiconductor film provided in the stacked body and extending in the stacking direction; a charge storage film provided between the semiconductor film and the first electrode layer; and a first intermediate insulating film provided between the charge storage film and the first electrode layer. The distance between the semiconductor film and the second portion is shorter than the distance between the semiconductor film and the first portion. The first intermediate insulating film extends in the stacking direction.

### CROSS-REFERENCE TO RELATED APPLICATION

This application is based upon and claims the benefit of priority from U.S. Provisional Patent Application 62/209,482 field on Aug. 25, 2015; the entire contents of which are incorporated herein by reference.

### FIELD

Embodiments described herein relate generally to a semiconductor memory device and a method for manufacturing same.

### BACKGROUND

A memory device of the three-dimensional structure has been proposed. The memory device includes a stacked body of a plurality of electrode layers each stacked with spacing. The electrode layer functions as a control gate in a memory cell. A memory hole is formed in the stacked body. A silicon body constituting a channel is provided on the sidewall of the memory hole via a charge storage film.

A problem is to improve the characteristics in the aforementioned device.

### BRIEF DESCRIPTION OF THE DRAWINGS

FIG. 1 is a schematic perspective view of a memory cell array of an embodiment;

FIG. 2A is a schematic cross-sectional view of part of the memory cell array of the embodiment, FIG. 2B is enlarged schematic cross-sectional view of part of a columnar part of the embodiment, and FIG. 2C is enlarged schematic cross-sectional view of part of an electrode layer of the embodiment; and

FIG. 3A to FIG. 7B are schematic cross-sectional views showing a method for manufacturing the semiconductor memory device of the embodiment.

### DETAILED DESCRIPTION

According to one embodiment, a semiconductor memory device includes a substrate; a stacked body provided on the substrate and including: a first electrode layer including a first portion and a second portion thicker than the first portion in stacking direction of the stacked body; and an insulating layer provided between the first electrode layer and the substrate; a semiconductor film provided in the stacked body and extending in the stacking direction; a charge storage film provided between the semiconductor film and the first electrode layer; and a first intermediate insulating film provided between the charge storage film and the first electrode layer. The distance between the semiconductor film and the second portion is shorter than the distance between the semiconductor film and the first portion. The first intermediate insulating film extends in the stacking direction.

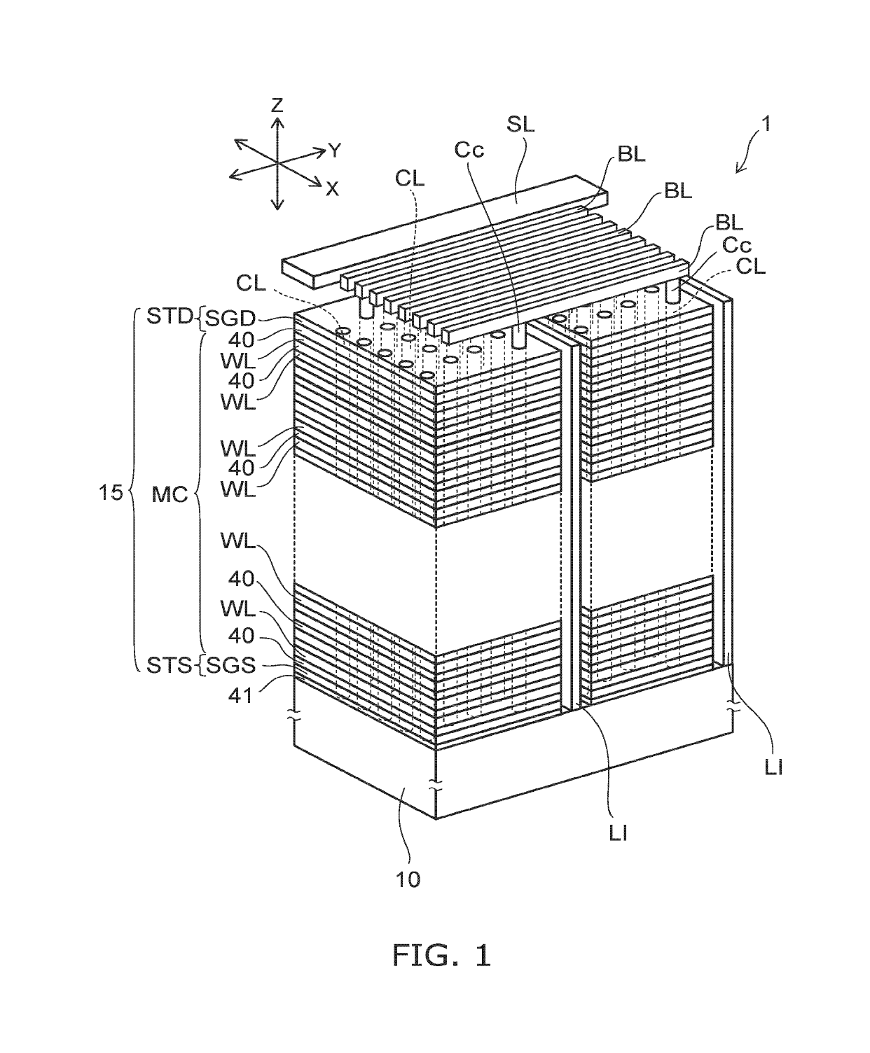

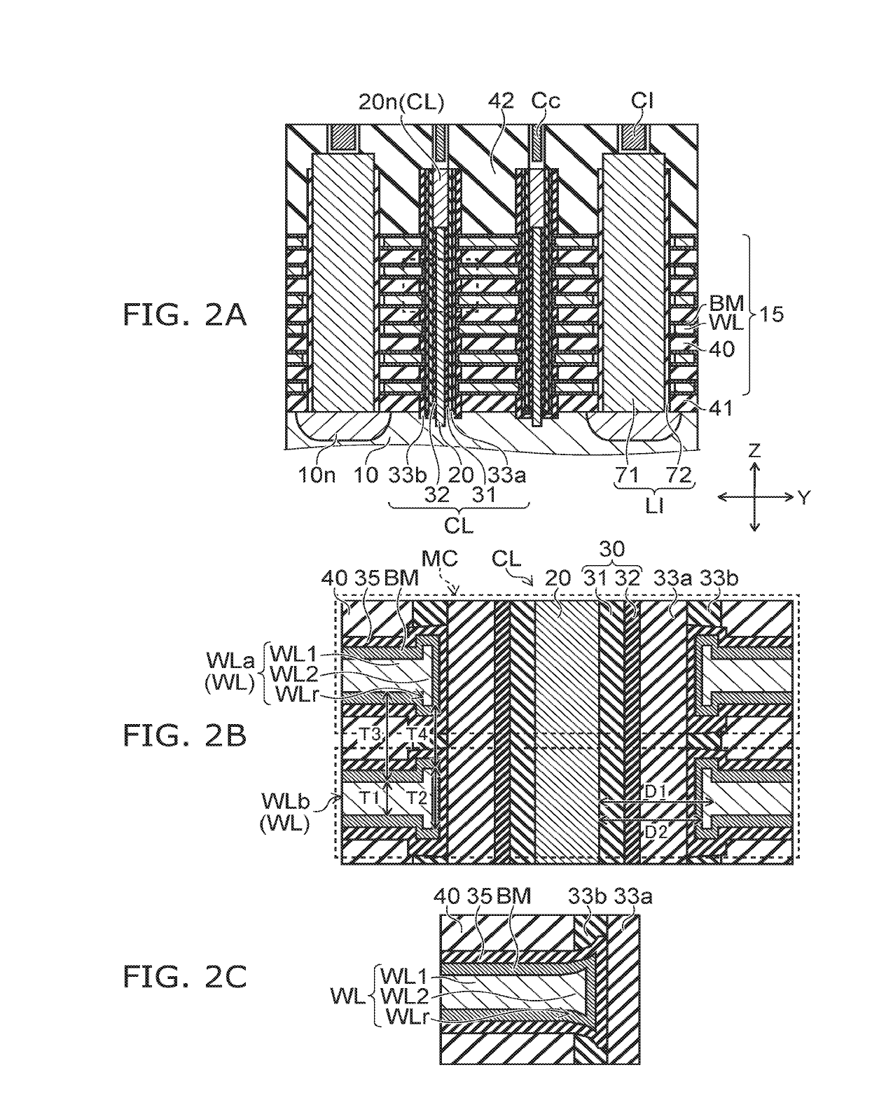

An example of the configuration of a memory cell array 1 of the embodiment is described with reference to FIGS. 1 and 2A.

FIG. 1 is a schematic perspective view of the memory cell array 1 of the embodiment. In FIG. 1, insulating layers and the like on the stacked body 15 are not shown for clarity of illustration.

FIG. 2A is a schematic sectional view of part of the memory cell array 1 of the embodiment. In FIG. 2A, the structure above the contact parts Cc, CI is not shown.

In FIG. 1, two directions orthogonal to each other are referred to as X-direction (first direction) and Y-direction (second direction). The direction orthogonal to the X-direction and the Y-direction (X-Y plane) is referred to as Z-direction (stacking direction). A plurality of electrode layers WL is stacked in the Z-direction.

As shown in FIGS. 1 and 2A, the memory cell array 1 includes a substrate 10, a stacked body 15, a plurality of columnar parts CL, a wiring layer LI, and an upper wiring. FIG. 1 shows a bit line BL and a source layer SL as the upper wiring.

The stacked body 15 is provided on the substrate 10 via an insulating layer 41. The stacked body 15 includes a source side select gate SGS, a drain side select gate SGD, a plurality of electrode layers WL, and a plurality of insulating layers 40.

The source side select gate SGS is provided in the lowermost layer of the stacked body 15. The drain side select gate SGD is provided in the uppermost layer of the stacked body 15.

The plurality of electrode layers WL is each stacked with spacing. The plurality of insulating layers 40 is provided between the plurality of electrode layers WL. The surface (upper surface, lower surface, and side surface) of the plurality of electrode layers WL is provided with e.g. a barrier film BM (conductive film). The number of electrode layers WL shown in the figure is illustrative only. The number of electrode layers WL is arbitrary.

The electrode layer WL includes a metal. The electrode layer WL includes at least one of e.g. tungsten, molybdenum, titanium nitride, and tungsten nitride. The electrode layer WL may include silicon or metal silicide. The source side select gate SGS and the drain side select gate SGD include the same material as the electrode layer WL. The insulating layer 40 includes e.g. silicon oxide film. The barrier film BM includes e.g. titanium. The barrier film BM includes a stacked film of titanium and titanium nitride.

The thickness of the drain side select gate SGD and the thickness of the source side select gate SGS are thicker than e.g. the thickness of one electrode layer WL. The drain side select gate SGD and the source side select gate SGS may be provided in a plurality. The thickness of the drain side select gate SGD and the thickness of the source side select gate SGS may be equal to or thinner than the thickness of one electrode layer WL. In this case, the drain side select gate SGD and the source side select gate SGS may be provided in a plurality as described above. The term “thickness” used herein refers to the thickness in the stacking direction (Z-direction) of the stacked body 15.

The stacked body 15 includes a plurality of columnar parts CL extending in the Z-direction. The columnar part CL is provided like e.g. a circular column or elliptical column. The plurality of columnar parts CL is provided in e.g. a staggered arrangement. Alternatively, the plurality of columnar parts CL may be provided in a square lattice along the X-direction and the Y-direction. The columnar part CL is electrically connected to the substrate 10.

The columnar part CL includes a channel body 20 and a memory film 30 shown in FIG. 2B. The memory film 30 is provided between the stacked body 15 and the channel body 20. The memory film 30 and the channel body 20 extend in the Z-direction.

The channel body 20 is shaped like e.g. a column. A core insulating film, for instance, may be provided inside the channel body 20. The channel body 20 is e.g. a silicon film composed primarily of silicon. The core insulating film includes e.g. silicon oxide film, and may include an air gap.

The stacked body 15 includes a wiring layer LI extending in the X-direction and the Z-direction in the stacked body 15. The wiring layer LI is sandwiched by the stacked body 15. The wiring layer LI includes a conductive film 71 and an insulating film 72. The insulating film 72 is in contact with the stacked body 15. The conductive film 71 is provided inside the insulating film 72.

The lower end of the conductive film 71 is electrically connected to the channel body 20 (semiconductor film) in the columnar parts CL through the semiconductor part 10n of the substrate 10. The upper end of the conductive film 71 is electrically connected to a control circuit, not shown, through the contact part CI and the source layer SL.

A plurality of bit lines BL is provided on the stacked body 15. The plurality of bit lines BL is separated from each other in the X-direction and extends in the Y-direction.

The upper end of the channel body 20 is electrically connected to the bit line BL through the contact part Cc. The lower end side of the channel body 20 is in contact with the substrate 10.

A plurality of channel bodies 20 each selected from one of the plurality of columnar parts CL separated in the Y-direction by the wiring layer LI are electrically connected to one common bit line BL.

A drain side select transistor STD is provided in the upper end part of the columnar part CL. A source side select transistor STS is provided in the lower end part of the columnar part CL.

The memory cell MC, the drain side select transistor STD, and the source side select transistor STS are vertical transistors in which a current flows in the stacking direction of the stacked body 15.

The select gate SGD, SGS functions as a gate electrode of the corresponding select transistor STD, STS, i.e., a select gate. An insulating film functioning as a gate insulating film of the select transistor STD, STS is provided between the corresponding select gate SGD, SGS and the channel body 20.

A plurality of memory cells MC is provided between the drain side select transistor STD and the source side select transistor STS. Each electrode layer WL serves as a control gate of the corresponding memory cell MC. The plurality of memory cells MC is each stacked with spacing.

The plurality of memory cells MC, the drain side select transistor STD, and the source side select transistor STS are series connected through the channel body 20 and constitute one memory string. Such memory strings are arranged in e.g. a staggered arrangement in the directions of a plane parallel to the X-Y plane. Thus, a plurality of memory cells MC is provided three-dimensionally in the X-direction, the Y-direction, and the Z-direction.

The semiconductor memory device of the embodiment can electrically and freely erase/write data and retain its memory content even when powered off.

An example of the memory cell MC of the embodiment is described with reference to FIG. 2B.

FIG. 2B is an enlarged schematic sectional view of part of the columnar part CL of the embodiment.

The memory cell MC is e.g. of the charge trap type. The memory cell MC includes an electrode layer WL, a channel body 20, a memory film 30, a first intermediate insulating film 33a, a second intermediate insulating film 33b, and a block film 35. The memory film 30 includes e.g. a charge storage film 32 and a tunnel insulating film 31.

The electrode layer WL includes a first portion WL1 and a second portion WL2. In the Z-direction, the thickness T2 of the second portion WL2 is thicker than the thickness T1 of the first portion WL1. That is, in the X-Z plane, the surface area of the second portion WL2 is larger than the surface area of the first portion WL1.

The distance D2 between the second portion WL2 and the channel body 20 is shorter than e.g. the distance D1 between the first portion WL1 and the channel body 20. The second portion WL2 is provided between the memory film 30 and the first portion WL1.

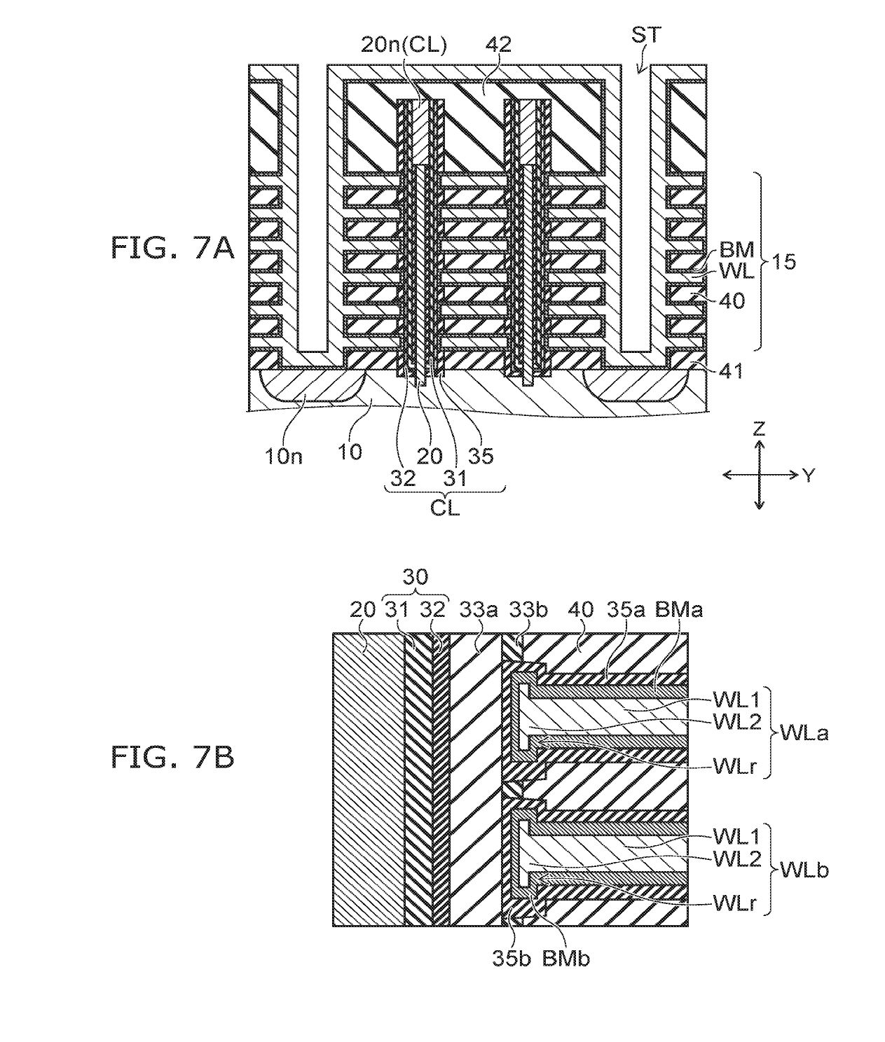

The plurality of electrode layers WL includes e.g. a first electrode layer WLa and a second electrode layer WLb (see FIG. 7B). The second electrode layer WLb is provided between the substrate 10 and the first electrode layer WLa. An insulating layer 40 is provided between the first electrode layer WLa and the second electrode layer WLb. In the distance between the first electrode layer WLa and the second electrode layer WLb, the distance T3 between the respective first portions WL1 is longer than the distance T4 between the respective second portions WL2. That is, the distance T3 between the first portion WL1 of the first electrode layer WLa and the first portion WL1 (third portion) of the second electrode layer WLb is longer than the distance T4 between the second portion WL2 of the first electrode layer WLa and the second portion WL2 (fourth portion) of the second electrode layer WLb. The ratio of the distance T4 to the distance T3 is 0.6 or more and 0.9 or less.

The plurality of electrode layers WL includes e.g. an inclined part WLr. The inclined part WLr is provided between the first portion WL1 and the second portion WL2. As described above, the thickness T2 of the second portion WL2 is thicker than the thickness T1 of the first portion WL1. Thus, an inclined part WLr is formed between the second portion WL2 and the first portion WL1. The inclined part WLr may have e.g. a nearly right-angled shape, or a curved surface as shown in e.g. FIG. 2C.

The first intermediate insulating film 33a is provided between the electrode layer WL and the memory film 30. The first intermediate insulating film 33a extends in the Z-direction. The first intermediate insulating film 33a includes the same material as the insulating layer 40. The first intermediate insulating film 33a includes e.g. silicon oxide film. In this case, the film density of the insulating layer 40 is lower than the film density of the first intermediate insulating film 33a. The second intermediate insulating film 33b is provided between the first intermediate insulating film 33a and the insulating layer 40. The second intermediate insulating film 33b is provided intermittently in the Z-direction.

The second intermediate insulating film 33b is sandwiched between e.g. the second portions WL2 of a plurality of electrode layers WL. That is, the second intermediate insulating film 33b is provided between the second portion WL2 of the first electrode layer WLa and the second portion WL2 of the second electrode layer WLb. In the Z-direction, the thickness of the second intermediate insulating film 33b is thinner than the thickness of the insulating layer 40.

The second intermediate insulating film 33b includes the same material as the first intermediate insulating film 33a and the insulating layer 40. The second intermediate insulating film 33b includes e.g. silicon oxide film. In this case, the film density of the second intermediate insulating film 33b is lower than the film density of the insulating layer 40 and the film density of the first intermediate insulating film 33a.

Here, the “film density” can be represented by e.g. etching rate. For instance, a film having a high etching rate has a low film density. A film having a low etching rate has a high film density. That is, the film density can be compared by etching the insulating films 33a, 33b and the insulating layer 40 described above. Thus, the configuration of the device can be confirmed.

That is, the film density of the first intermediate insulating film 33a is the highest. The film density of the insulating layer 40 is the next highest. The film density of the second intermediate insulating film 33b is the lowest. In this case, the etching rate of the second intermediate insulating film 33b is the highest. The etching rate of the insulating layer 40 is the next highest. The etching rate of the first intermediate insulating film 33a is the lowest.

The etching rate is represented in e.g. length per unit time (nm/min). The film density is represented in e.g. weight per unit volume (g/cm³).

The memory film 30 is provided between the first intermediate insulating film 33a and the channel body 20. In the memory film 30, the tunnel insulating film 31 is in contact with the channel body 20. The charge storage film 32 is in contact with the first intermediate insulating film 33a.

The block film 35 is integrally provided between the electrode layer WL and the first intermediate insulating film 33a, between the electrode layer WL and the second intermediate insulating film 33b, and between the electrode layer WL and the insulating layer 40. A barrier film BM is provided between the electrode layer WL and the block film 35.

The block film 35 and the barrier film BM are provided around each of the plurality of electrode layers WL.

The channel body 20 functions as a channel in the memory cell MC. The electrode layer WL functions as a control gate of the memory cell MC. The charge storage film 32 functions as a data storage layer for accumulating charge injected from the channel body 20. That is, the memory cell MC is formed in the crossing portion of the channel body 20 and each electrode layer WL. The memory cell MC has a structure in which the control gate surrounds the channel.

The charge storage film 32 includes a large number of trap sites for trapping charge. The charge storage film 32 includes at least one of e.g. silicon nitride film and hafnium oxide.

The tunnel insulating film 31 serves as a potential barrier when charge is injected from the channel body 20 into the charge storage film 32, or when the charge accumulated in the charge storage film 32 is diffused into the channel body 20. The tunnel insulating film 31 is e.g. a silicon oxide film. Alternatively, the tunnel insulating film 31 may be a stacked film (ONO film) of the structure in which a silicon nitride film is sandwiched by a pair of silicon oxide films. The tunnel insulating film 31 made of ONO film enables erase operation at lower electric field than a monolayer of silicon oxide film.

The block film 35 and the first intermediate insulating film 33a prevent the charge accumulated in the charge storage film 32 from diffusing into the electrode layer WL. The block film 35 includes at least one of e.g. hafnium, aluminum, zirconium, and lanthanum. The block film 35 is made of a material having higher permittivity (high dielectric oxide film, high-k film) than silicon nitride film.

The block film 35 includes e.g. a first cap film and a second cap film. The second cap film is placed between the electrode layer WL and the first intermediate insulating film 33a. The second cap film is e.g. a silicon oxide film.

The first cap film is provided between the second cap film and the electrode layer WL. The first cap film is a film having higher permittivity than the second cap film. The first cap film includes at least one of e.g. hafnium, aluminum, zirconium, and lanthanum described above. The first cap film is made of at least one of e.g. silicon nitride film and aluminum oxide. Providing the first cap film can suppress back tunneling electrons injected from the electrode layer WL at erase time. That is, the block film 35 is a stacked film of silicon oxide film and one of silicon nitride film and high dielectric oxide film. This can enhance the charge blocking capability.

For instance, the block film 35 may be provided in the columnar part CL. In this case, the first intermediate insulating film 33a may include the same material as the block film 35 described above.

In the Z-direction, the thickness of the block film 35 and the thickness of the barrier film BM are significantly thinner than e.g. the thickness of the insulating layer 40, the thickness of the second intermediate insulating film 33b, and the thickness T1, T2 of the electrode layer WL. In this case, the ratio of the thickness of the second intermediate insulating film to the thickness of the insulating layer 40 is 0.6 or more and 0.9 or less.

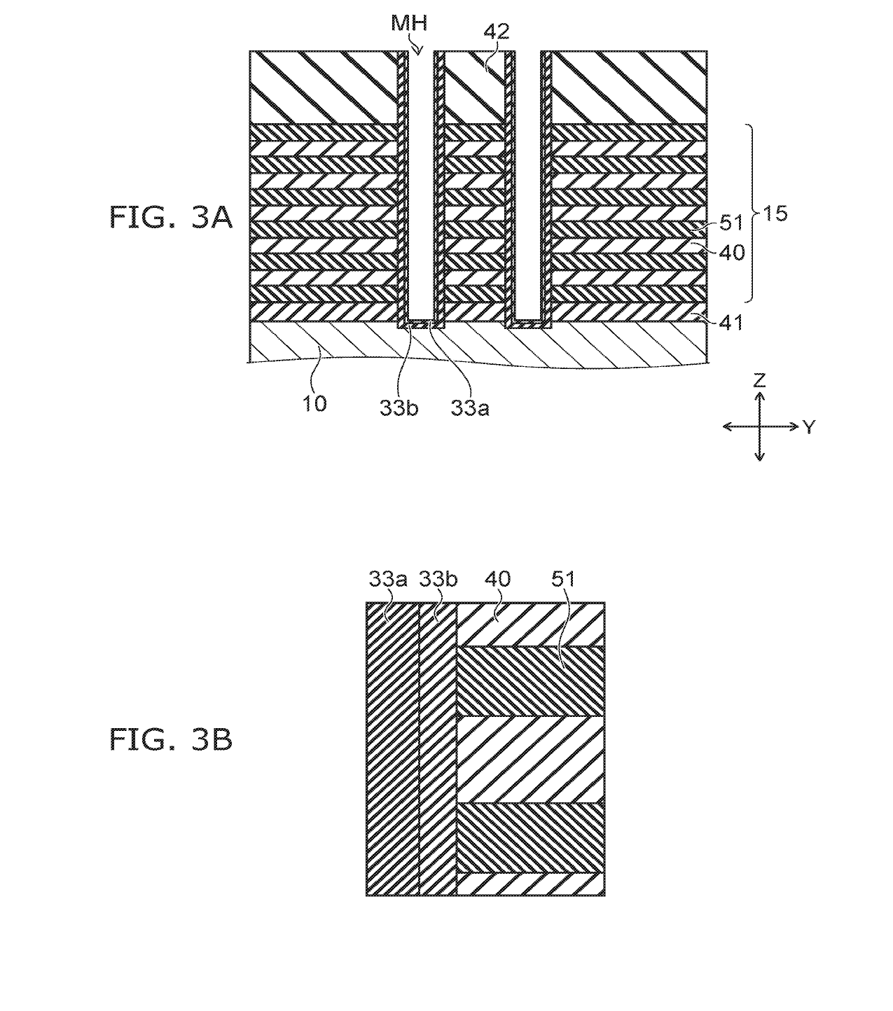

A method for manufacturing a semiconductor memory device of the embodiment is described with reference to FIGS. 3A to 7B. With regard to the aforementioned configuration, the description of similar contents is partially omitted.

FIGS. 3A, 4A, 5, 6A, and 7A are schematic sectional views of the semiconductor device of the embodiment. FIGS. 3B, 4B, 6B, and 7B are enlarged schematic sectional views of the vicinity of the columnar part of the embodiment.

As shown in FIGS. 3A and 3B, a stacked body 15 is formed on a substrate 10 via an insulating film 41. A plurality of sacrificial layers 51 (first layers) and a plurality of insulating layers 40 (second layers) are alternately stacked in the stacked body 15. The number of stacked layers of the stacked body 15 is arbitrary. The sacrificial layer 51 is made of e.g. silicon nitride film. The insulating layer 40 is made of e.g. silicon oxide film.

Next, an insulating layer 42 is formed on the stacked body 15. The insulating layer 42 is made of e.g. silicon oxide film. Then, a hole MH penetrating through the insulating layer 42 and the stacked body 15 to the substrate 10 is formed. A second intermediate insulating film 33b is formed on the inner wall of the hole MH. A first intermediate insulating film 33a is formed inside the second intermediate insulating film 33b.

The second intermediate insulating film 33b is made of e.g. silicon oxide film. The first intermediate insulating film 33a is made of silicon nitride film. The first intermediate insulating film 33a is made of a material including e.g. silicon and enabling radical oxidation.

Then, the first intermediate insulating film 33a is subjected to radical oxidation. Thus, a silicon oxide film is formed on the first intermediate insulating film 33a. At this time, the second intermediate insulating film 33b has been formed on the side surface of the sacrificial layer 51. Thus, the sacrificial layer 51 is not oxidized.

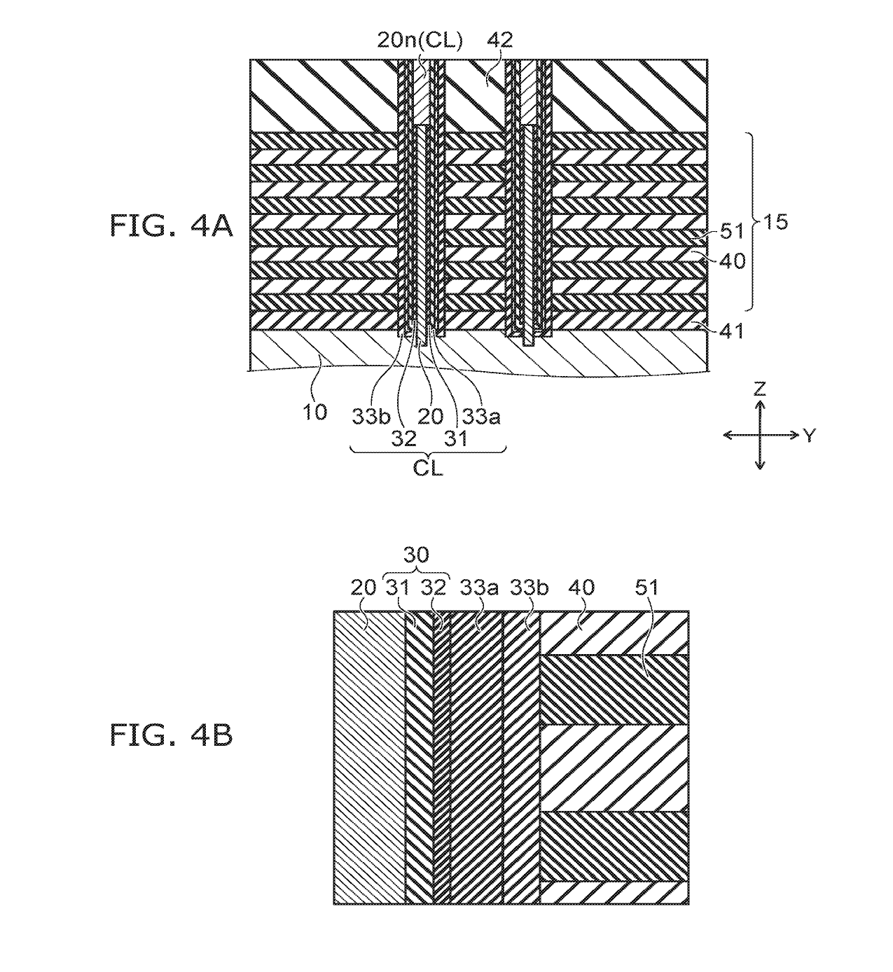

As shown in FIGS. 4A and 4B, a memory film 30 is formed inside the radical-oxidized first intermediate insulating film 33a. A channel body 20 is formed inside the memory film 30. A semiconductor part 20n is formed on the channel body 20. Thus, a columnar part CL is formed. Then, an insulating layer 42 is further formed on the upper surface of the columnar part CL and the upper surface of the insulating layer 42.

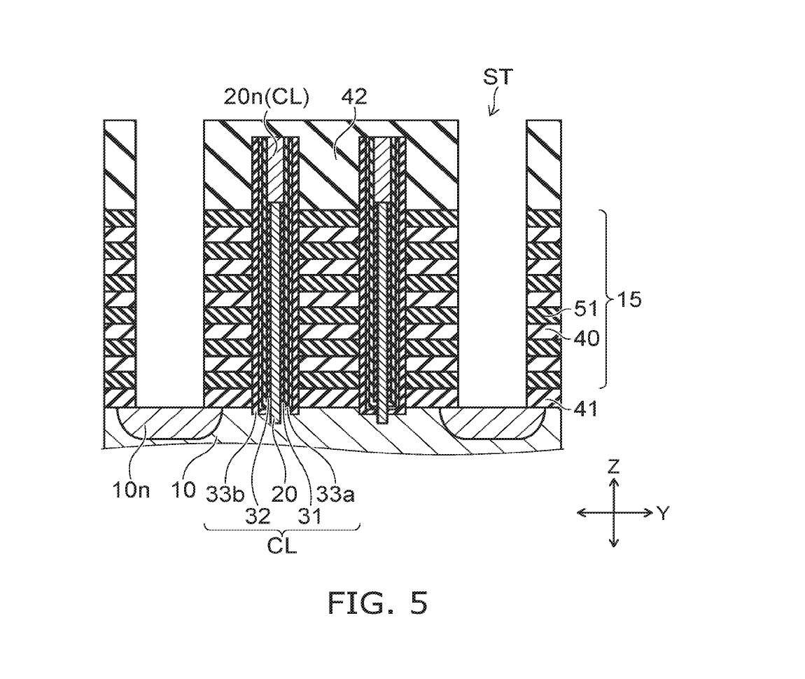

As shown in FIG. 5, a slit ST penetrating through the insulating layer 42 and the stacked body 15 to the substrate 10 is formed. The slit ST extends in the X-direction. The side surface of the plurality of sacrificial layers 51 and the side surface of the plurality of insulating layers 40 are exposed at the side surface of the slit ST. The substrate 10 is exposed at the bottom surface of the slit ST. Then, the portion of the substrate 10 exposed to the slit ST is doped with e.g. n-type impurity (e.g., phosphorus). Thus, a semiconductor part 10n is formed. Alternatively, the substrate 10 may be doped with e.g. p-type impurity (e.g., boron).

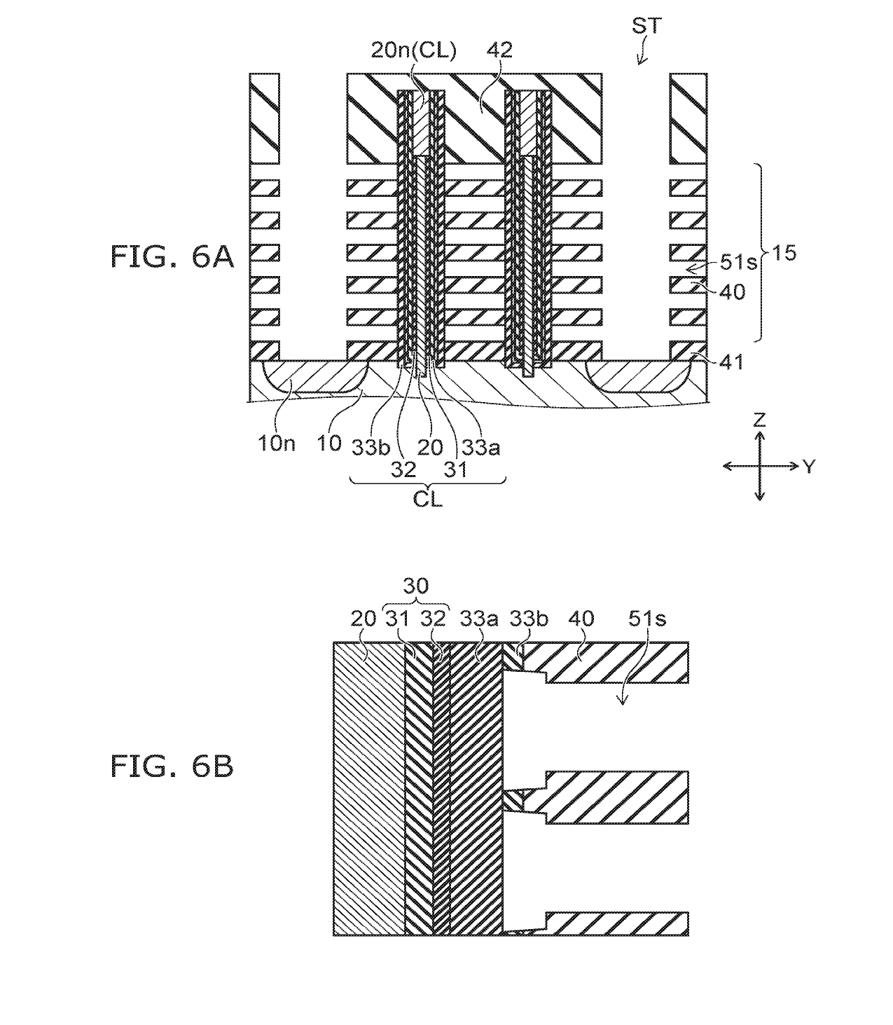

As shown in FIGS. 6A and 6B, the plurality of sacrificial layers 51 is removed by using e.g. wet etching technique through the slit ST. Thus, a space 51s is formed in the portion in which the plurality of sacrificial layers 51 was formed. The wet etching technique uses e.g. phosphoric acid (hot H₃PO₄).

At this time, part of the second intermediate insulating film 33b and part of the insulating layer 40 formed around the sacrificial layer 51 are also removed. Thus, the second intermediate insulating film 33b is separated in the Z-direction. On the other hand, the first intermediate insulating film 33a is scarcely removed compared with the second intermediate insulating film 33b and the insulating layer 40.

That is, in using the aforementioned wet etching technique, the etching rate of the second intermediate insulating film 33b is higher than the etching rate of the first intermediate insulating film 33a and the insulating layer 40. The etching rate of the insulating layer 40 is higher than the etching rate of the first intermediate insulating film 33a. Thus, the second intermediate insulating film 33b is preferentially removed. Accordingly, a large portion of the space 51s is formed near the columnar part CL.

As shown in FIGS. 7A and 7B, a block film 35 is formed on the wall surface (side surface, upper surface, and lower surface) of the space 51s. A barrier film BM is formed inside the block film 35. An electrode layer WL is formed inside the barrier film BM. The block film 35, the barrier film BM, and the electrode layer WL are formed also on the wall surface of the slit ST and the upper surface of the insulating layer 42.

As shown in FIG. 7B, the electrode layer WL includes a first portion WL1, a second portion WL2, and an inclined part WLr. The first portion WL1 is formed between the plurality of insulating layers 40. The second portion WL2 is formed between the second intermediate insulating films 33b separated in the Z-direction. In the Z-direction, the thickness T2 of the second portion WL2 is thicker than the thickness T1 of the first portion WL1. That is, in the X-Z plane, the surface area of the second portion WL2 is formed larger than the surface area of the first portion WL1.

Next, as shown in FIG. 2A, the block film 35, the barrier film BM, and the electrode layer WL formed on the wall surface of the slit ST and the upper surface of the insulating layer 42 are removed. Thus, the side surface of the plurality of insulating layers 40 and the side surface of the plurality of electrode layers WL are exposed at the side surface of the slit ST. The semiconductor part 10n of the substrate 10 is exposed at the bottom surface of the slit ST.

Then, an insulating film 72 is formed on the side surface of the slit ST. A conductive film 71 is formed inside the insulating film 72 and at the bottom surface of the slit ST. Contact parts CI, Cc are formed on the upper surface of the conductive film 71 and the upper surface of the columnar part CL. Then, upper wirings and the like connected to the contact parts CI, Cc are formed. Thus, the semiconductor memory device of the embodiment is formed.

Effects in the embodiment are now described.

According to the embodiment, the plurality of electrode layers WL includes a first portion WL1 and a second portion WL2. The thickness T2 of the second portion WL2 is thicker than the thickness T1 of the first portion WL1. That is, the surface area of the side surface of the second portion WL2 is larger than the surface area of the side surface of the first portion WL1. Thus, the surface area of the electrode layer WL opposed to the charge storage film 32 can be increased. This can improve the characteristics of the semiconductor memory device.

For instance, the thickness of the electrode layer WL may be thinned toward the columnar part CL. That is, the thickness of the electrode layer WL nearest to the charge storage film 32 is made thinner than the thickness T1 of the first portion WL1 described above. This may decrease the surface area of the electrode layer WL opposed to the charge storage film 32. Thus, at the time of controlling the cell part such as in write operation, application of electric field to the cell part is made difficult. Accordingly, the voltage applied to the electrode layer WL may be increased. This may cause degradation around the memory cell MC.

In contrast, according to the embodiment, the second portion WL2 is nearer to the columnar part CL than the first portion WL1, and thicker than the first portion WL1. Thus, the surface area of the electrode layer WL opposed to the charge storage film 32 is large. Thus, application of electric field to the cell part is facilitated. This can decrease e.g. the write voltage and erase voltage. In addition to the foregoing, the block film 35 made of high dielectric film is provided between the second portion WL2 and the columnar part CL. Thus, the coupling ratio can be increased. This can further decrease the voltage necessary for the operation of the cell part.

In addition to the foregoing, according to the embodiment, the second intermediate insulating film 33b is provided between the first intermediate insulating film 33a and the insulating layer 40. The second intermediate insulating film 33b is sandwiched between the second portions WL2 of a plurality of electrode layers WL.

For instance, there may be a case where the first intermediate insulating film 33a is in contact with the insulating layer 40. Then, the second intermediate insulating film 33b is not provided between the first intermediate insulating film 33a and the insulating layer 40. In this case, when the first intermediate insulating film 33a is subjected to oxidation processing, the sacrificial layer 51 may also be oxidized simultaneously. Thus, the oxidized portion of the sacrificial layer 51 may fail to be completely removed. In this case, the thickness of the formed electrode layer WL may be thinned toward the columnar part CL as in the aforementioned example. This may cause degradation around the memory cell MC.

In contrast, according to the embodiment, the second intermediate insulating film 33b is formed.

This can suppress oxidation of the sacrificial layer 51 when the first intermediate insulating film 33a is subjected to oxidation processing. Thus, an electrode layer WL having a large surface area can be formed. Furthermore, the charge storage film 32 is not exposed to the space 51s when the sacrificial layer 51 is removed. This can suppress degradation of the charge storage film 32. That is, the characteristics of the semiconductor memory device can be improved.

Furthermore, according to the embodiment, the film density of the first intermediate insulating film 33a is the highest. The film density of the insulating layer 40 is the next highest. The film density of the second intermediate insulating film 33b is the lowest. In this case, the etching rate of the second intermediate insulating film 33b is the highest. The etching rate of the insulating layer 40 is the next highest. The etching rate of the first intermediate insulating film 33a is the lowest. Thus, the space 51s for forming the second portion WL2 of the electrode layer WL can be formed. Furthermore, the degradation of the surface of the charge storage film 32 can be prevented when the sacrificial layer 51 is removed. That is, the characteristics of the semiconductor memory device can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a substrate;
a stacked body provided on the substrate and including:
a first electrode layer including a first portion and a second portion, a thickness of the second portion being thicker than a thickness of the first portion in stacking direction of the stacked body; and
an insulating layer provided between the first electrode layer and the substrate;
a semiconductor film provided in the stacked body and extending in the stacking direction, a distance between the semiconductor film and the second portion being shorter than a distance between the semiconductor film and the first portion;
a charge storage film provided between the semiconductor film and the first electrode layer; and
a first intermediate insulating film provided between the charge storage film and the first electrode layer, the first intermediate insulating film extending in the stacking direction.

2. The device according to claim 1, wherein
the stacked body includes a second electrode layer between the insulating layer and the substrate,
the second electrode layer includes:
a third portion; and
a fourth portion, a thickness of the fourth portion being thicker than a thickness of the third portion in the stacking direction, and
ratio of distance between the second portion of the first electrode layer and the fourth portion of the second electrode layer to distance between the first portion of the first electrode layer and the third portion of the second electrode layer is 0.6 or more and 0.9 or less.

3. The device according to claim 1, wherein the first electrode layer includes an inclined part between the first portion and the second portion.

4. The device according to claim 3, wherein the inclined part has a curved surface.

5. The device according to claim 1, wherein the insulating layer includes a same material as the first intermediate insulating film.

6. The device according to claim 1, wherein the insulating layer and the first intermediate insulating film include silicon oxide film.

7. The device according to claim 6, wherein film density of the insulating layer is lower than film density of the first intermediate insulating film.

8. The device according to claim 6, further comprising:
a second intermediate insulating film provided between the insulating layer and the first intermediate insulating film,
wherein the second intermediate insulating film includes silicon oxide film.

9. The device according to claim 8, wherein film density of the second intermediate insulating film is lower than film density of the insulating layer and film density of the first intermediate insulating film.

10. The device according to claim 8, wherein, in the stacking direction, thickness of the insulating layer is thicker than thickness of the second intermediate insulating film.

11. The device according to claim 8, wherein
the stacked body includes a second electrode layer between the insulating layer and the substrate,
the second electrode layer includes:
a third portion; and
a fourth portion, a thickness of the fourth portion being thicker than a thickness of the third portion in the stacking direction, and
the second intermediate insulating film is provided between the second portion of the first electrode layer and the fourth portion of the second electrode layer.

12. The device according to claim 1, further comprising:
a block film integrally provided between the first electrode layer and the first intermediate insulating film and between the first electrode layer and the insulating layer.

13. The device according to claim 12, further comprising:
a barrier film provided between the first electrode layer and the block film.

14. A semiconductor memory device comprising:
a substrate;
a stacked body provided on the substrate and including:
a first electrode layer and a second electrode layer stacked with spacing; and
an insulating layer provided between the first electrode layer and the second electrode layer;
a semiconductor film provided in the stacked body and extending in stacking direction of the stacked body;
a charge storage film provided between the semiconductor film and the first electrode layer and between the semiconductor film and the second electrode layer;
a first intermediate insulating film provided between the charge storage film and the first electrode layer and between the charge storage film and the second electrode layer and extending in the stacking direction; and
a second intermediate insulating film provided between the first intermediate insulating film and the insulating layer and between the first electrode layer and the second electrode layer, a thickness of the second intermediate insulating film being thinner than a thickness of the insulating layer in the stacking direction.

15. The device according to claim 14, wherein ratio of the thickness of the second intermediate insulating film to the thickness of the insulating layer is 0.6 or more and 0.9 or less.

16. The device according to claim 14, wherein the insulating layer, the first intermediate insulating film, and the second intermediate insulating film include silicon oxide film.

17. The device according to claim 16, wherein film density of the second intermediate insulating film is lower than film density of the insulating layer and film density of the first intermediate insulating film.

18. The device according to claim 14, wherein
the first electrode layer includes:
a first portion; and
a second portion, a thickness of the second portion being thicker than a thickness of the first portion in the stacking direction,
the second electrode layer includes:
a third portion; and
a fourth portion, a thickness of the fourth portion being thicker than a thickness of the third portion in the stacking direction, and
the second intermediate insulating film is provided between the second portion and the fourth portion.

19. The device according to claim 18, wherein
the first electrode layer includes a first inclined part between the first portion and the second portion, and
the second electrode layer includes a second inclined part between the third portion and the fourth portion.

20. A method for manufacturing a semiconductor memory device, comprising:
forming a stacked body on a substrate, the stacked body including:
a plurality of first layers each stacked with spacing; and
second layers stacked alternately with the plurality of first layers;
forming a hole penetrating through the stacked body to the substrate;
forming a first intermediate insulating film and a second intermediate insulating film on an inner wall of the hole, the second intermediate insulating film being formed between the inner wall of the hole and the first intermediate insulating film;
oxidizing the first intermediate insulating film;
forming a charge storage film inside the first intermediate insulating film;
forming a semiconductor film inside the charge storage film;
forming a slit penetrating through the stacked body to the substrate;
forming a plurality of spaces by removing the plurality of first layers through the slit;
separating the second intermediate insulating film in stacking direction of the stacked body through the plurality of spaces; and
forming a plurality of electrode layers in the plurality of spaces, the plurality of electrode layers including:
a first portion formed between the plurality of second layers; and
a second portion formed between the second intermediate insulating films separated in the stacking direction, a thickness of the second portion being thicker than a thickness of the first portion.
